(19) United States
(12) Patent Application Publication
(10) Pub. No.: US 2019/0137541 A1
(43) Pub. Date: May 9, 2019

(54) RUBBER SOCKET AND METHOD FOR MANUFACTURING SAME

(71) Applicant: Hyung Ik KIM, Chongju-si (KR)

(72) Inventor: Hyung Ik KIM, Chongju-si (KR)

(21) Appl. No.: 16/308,415

(22) PCT Filed: Jun. 2, 2017
(86) PCT No.: PCT/KR2017/005824

§ 371 Date: Dec. 7, 2018

(30) Foreign Application Priority Data
Jun. 10, 2016 (KR) 10-2016-0072628

(51) Int. Cl. G01R 1/04; G01R 3/00; G01R 31/28

(52) U.S. Cl. CPC G01R 1/0416; G01R 31/28; G01R 3/00

(57) ABSTRACT

A rubber socket comprises a lower film, an upper film, an electrical connection member, and a rubber layer. The lower film comprises a plurality of lower electrode parts coupled to a synthetic resin film. The upper film is arranged in parallel with and spaced apart from the lower film, and comprises a plurality of upper electrode parts. The electrical connection member comprises: a soft substrate, which physically connects the lower electrode parts and the upper electrode parts, has a flat plate shape, and is easily bent by an external force; and a plurality of electrical connection patterns, which are longitudinally formed on one side surface of the soft substrate to electrically connect the lower electrode parts and the upper electrode parts. The rubber layer comprises an elastic material, is disposed between the lower film and the upper film, has all the electrical connection members buried therein, and constantly maintains a distance between the lower film and the upper film.

### TECHNICAL FIELD

The present invention relates to a rubber socket and a method for manufacturing the same and more specifically, to a rubber socket and a method for manufacturing a rubber socket the lifespan of which is increased and the credibility of which is improved.

### DESCRIPTION OF THE RELATED ART

The step of testing a semiconductor, closely associated with the credibility thereof, highly important in the process of manufacturing semiconductors. Although semiconductors are tested after packaged, semiconductors have to be tested intermediately even before packaged.

In order to test the electrical feature of a semiconductor before or after the process of packing the semiconductor, electricity has to be supplied to the pad of the semiconductor. However, it is almost impossible to directly supply electricity to the pad with high-density circuits. Thus, an anisotropic pad is disposed between a semiconductor and a test stage. Electricity is supplied to the test stage, passes through the anisotropic pad and is supplied to the semiconductor such that a test is performed.

A conventional anisotropic pad has a structure in which insulation silicone rubber is positioned between electrodes, and a silicone resin, in which conductive particles are dispersed, is hardened in upper and lower electrodes, such that electricity connects on the upper and lower sides of the electrodes.

Due this, conductive particles are dispersed differently depending on each electrode. Thus, credibility varies from product to product. When 30% or more of the thickness of the electrode is pressed, such a conductive particle tears silicone little by little and moves, thereby reducing the quality and life span of products.

Additionally, when the height of silicone increases, the quality is weakened, while when the pitch of an electrode decreases, the lifespan of a product is and the electrical feature of a product is adversely affected.

Research into the technology where an electrical wire is inserted into silicone has been underway as another one in relation to an anisotropic pad. However, when an electrical wire is inserted into silicone rubber, the electrical wire and a pad are buried in the silicone rubber while tests are repeatedly performed.

Korean Patent No. 10-1418590 and Korean Patent No. 10-1544644 disclose a technology regarding an anisotropic pad using wire bonding as a means to solve the above-described problems. However, when wire bonding is used, a pad with the resolution more than or equal to 0.1 mm is needed to connect a wire and a pad. Further, when the cross section area of a wire becomes small and the size of a signal increases, the wire series as resistance, the signal is distorted by generated heat, or the wire is easily cut.

At time when the density of semiconductors increases, it is hard to connect a wire with a pad the of which smaller than 0.1 mm. Due to is semiconductor products are not readily tested. Further, when the size of a pad becomes smaller, the pad is not stably connected with a wire, thereby reducing the lifespan of a rubber socket.

There are patent documents including Korean Patent No. 10-1418590 titled “WIRED CONTACT RUBBER AND METHOD THEREOF” and Korean Patent No. 10-1544844 titled “WIRED RUBBER CONTACT AND METHOD OF MANUFACTURING THE SAME”.

### DETAILED DESCRIPTION OF THE INVENTION

### Technical Problems

As a means to solve the above-described problems, the present invention is directed to providing a rubber socket the lifespan of which is increased and the credibility of which improved.

The present invention is also directed to providing a method for manufacturing the above-described rubber socket.

### Technical Solutions

As a means to achieve the above-described purpose, a rubber socket includes a lower film, an upper film, an electrical connection member and a rubber layer. The lower film includes a plurality of lower electrode parts coupled to a synthetic resin film. The upper film is spaced apart from the lower film, is arranged in parallel with the lower film and includes a plurality of upper electrode parts. The electrical connection member physically connects the lower electrode parts and the upper electrode parts, and includes a soft substrate which has a flat plate shape and is easily bent by an external force and a plurality of electrical connection patterns which are vertically formed on one lateral surface of the soft substrate and electrically connects the lower electrode parts and the upper electrode parts. The rubber layer includes an elastic material, is disposed between the lower film and the upper film, entirely buries the electrical connection members and constantly maintains the distance between the upper film and the lower film.

In an embodiment, the distance between the upper electrode parts is shorter than the distance between the lower electrode parts, and in each electrical connection member, the distance between the upper portions of adjacent electrical connection patterns may be shorter than the distance between the lower portions of adjacent electrical connection patterns.

In an embodiment, the electrical connection member may further include a central opening which is opened and formed between the electrical connection patterns.

In an embodiment, the electrical connection member covers the electrical connection patterns and further includes an upper coating having an upper opening one side of which extends in a direction perpendicular to the direction in which the electrical connection patterns extend. The lower opening is disposed on the opposite side of the upper opening with respect to the electrical connection patterns, and the soft substrate may have a lower opening which is disposed on the opposite side of the lower opening and extends in a direction perpendicular to the direction in which the electrical connection patterns extend.

As a means to achieve the above-described purpose, a rubber socket includes a lower film including a plurality of lower electrode parts coupled to a synthetic resin film, an upper film spaced apart from the lower film, arranged in parallel with the lower film and including a plurality of upper electrode parts, a soft substrate having a flat plate shape and easily bent by an external force, an electrical connection member including a plurality electrical connection patterns which are vertically formed on one lateral surface of the soft substrate and electrically connects the lower electrode parts and the upper electrode parts, and a rubber layer disposed between the lower film and the upper film and entirely burying the electrical connection members. A method for manufacturing a rubber socket includes forming a plurality of primitive lower electrode parts and lower joint parts protruding from the primitive lower electrode parts in the central area of a lower film, forming a plurality of primitive upper electrode parts and upper joint parts protruding from the primitive upper electrode parts in the central area of an upper film, coupling the lower portion of the electrical connection pattern and the lower joint part, coupling the upper portion of the electrical connection pattern and the upper joint part and finally, forming a rubber layer between the lower film and the upper film.

In an embodiment, the step of coupling the lower portion of the electrical connection pattern and the lower joint part may include welding or soldering the lower portion of the electrical connection pattern and the lower joint part by means of ultrasonic waves and heat in the state where the lower portion of the electrical connection pattern and the lower joint part are pressed.

In an embodiment, the steps of coupling the lower portion of the electrical connection pattern and the lower joint part and coupling the upper portion of the electrical connection pattern and the upper joint part may be simultaneously performed. In another embodiment, the steps of coupling the lower portion of the electrical connection pattern and the lower joint part and coupling the upper portion of the electrical connection pattern and the upper joint part may be performed one by one.

As a means to achieve the above-described purpose, a rubber socket includes a plurality of perpendicular circuit boards and a plurality of adhesion layers. The perpendicular circuit boards are perpendicularly piled. Each of the perpendicular circuit board includes a rubber substrate and a plurality of electrical connection patterns. The rubber substrate has a flat plate shape which extends vertically, and is temporarily deformed by an external force and returns to the original shape thereof when the external force is removed. Each of the electrical connection pattern includes a lower contact part disposed only on part of the lower surface of the rubber substrate and exposed toward the lower portion of the rubber substrate, an upper contact part disposed only on part of the upper surface of the rubber substrate and exposed toward the upper portion of the rubber substrate, and a connection part vertically extending and connecting the lower contact part and the upper contact part on one lateral surface of the rubber substrate. The adhesion layers are disposed between adjacent perpendicular circuit boards and bond the adjacent perpendicular circuit boards such that the adjacent perpendicular circuit boards are integrally piled.

In an embodiment, the rubber substrate has one lateral surface on which the connection part is disposed and which has a flat plate shape and the other lateral surface which is on the opposite side of the connection part and has a concave shape so as to form a buffer space. In an embodiment, the rubber socket may further include a thin buffer film which is thinner than the rubber substrate, is disposed between the rubber substrate and the electrical connection patterns and has a lower deformation level than the rubber substrate with respect to the external force.

As a means to achieve the above-described purpose, a method for manufacturing a rubber socket includes molding silicone rubber or synthetic rubber so as to form a rubber substrate which has a flat plate shape vertically extending, and is temporarily deformed by an external force and returns to the original shape thereof when the external force is removed, forming a plurality of electrical connection members, which have a conductive material and respectively include a lower contact part, an upper contact part and a connection part for connecting the lower contact part and the upper contact part, on part of the lower surface, part of the upper surface and one lateral surface of the rubber substrate, so as to form a perpendicular circuit board, vertically piling a plurality of perpendicular circuit boards such that the lower contact parts and upper contact parts are respectively exposed toward the lower and upper portions of the rubber substrate, and finally, coupling the perpendicular circuit boards vertically piled.

In one embodiment, the method for manufacturing a rubber socket further includes forming a thin buffer film, which is thinner than the rubber substrate and has a lower deformation level than the rubber substrate with respect to the external force, on the lower surface, the upper surface and one lateral surface of the rubber substrate, and the step of forming electrical connection members may include forming the lower contact part, the upper contact part and the connection part on the thin buffer film.

### Advantageous Effects

According to the above-described embodiment of the present invention, an electrical connection member is used instead of a wire so as to connect lower electrode parts of a lower film and upper electrode parts of an upper film. In this case, the upper portion of the electrical connection member is connected in parallel to the lower surface of the upper electrode part, the lower portion of the electrical connection member is connected in parallel to the upper surface of the lower electrode part, and the central portion of the electrical connection member is connected to the upper electrode part and lower electrode part in the state where the central portion of the electrical connection member perpendicularly curved between the upper electrode part and lower electrode part.

When the electrical connection member includes a soft substrate and an electrical connection pattern, external pressure may be effectively dispersed in the case in which an external shock is applied and a semiconductor chip is repeatedly tested.

Additionally, the width of the electrical connection pattern formed on the soft substrate may be controlled such that the surface are of the electrical connection pattern is expanded, thereby reducing resistance.

Additionally, the electrical connection pattern and the soft substrate are integrally formed so as to prevent the electrical connection pattern from being cut, thereby making possible to increase the lifespan of a rubber socket and improve the credibility of the same.

Additionally, the density of a semiconductor chip is improved. Thus, even when the distance between adjacent chip electrode pads becomes short, the shape of the electrical connection pattern or the gap between attached upper electrode parts is controlled without reducing the distance between stage electrode pads of a stage short such that a test may be easily performed.

Additionally, the shape of the electrical connection pattern may be configured to have any shape. Thus, an optimum test device may be provided according to a type of test.

Additionally, parallelism of a thin film patterned film be the upper and lower films is controlled without precise alignment, and an electrical connection member adheres between the upper and lower films, such that an electric signal pathway for exactly delivering a signal may be made.

Additionally, a thermal compression member includes an incline compression part by means of ultrasonic bonding, and heats and compresses the electrical connection pattern with respect to the electrode pads so as to sold y couple the electrical connection pattern to the electrode pads, thereby making it possible to increase the lifespan of a rubber socket and improve the credibility of the same.

Additionally, the electrical connection pattern is completely buried inside a rubber layer without sticking out of a rubber socket. Thus, the end portion of a rubber socket is not pushed inward, thereby making it possible to increase the lifespan of the rubber socket, improve the design of the rubber socket and prevent damage to a semiconductor chip for a test.

According to the above-described embodiment of the present invent rubber socket may effectively disperse external pressure using a plurality of perpendicular circuit boards piled perpendicularly, instead of a wire or a pad, in the case in which an external shock is applied and a semiconductor chip is repeatedly tested.

Additionally, the width of the electrical connection pattern of the perpendicular circuit board may be controlled such that the surface are of the electrical connection pattern is expanded, thereby reducing resistance.

Additionally, the electrical connection pattern and the perpendicular circuit board are integrally formed so as to prevent the electrical connection pattern being cut, thereby making it possible to increase the lifespan of a rubber socket and improve the credibility of the same.

Additionally, the density of a semiconductor chip is improved. Thus, even when the distance between adjacent chip electrode pads becomes short, a high-density semiconductor chip may be easily tested only by controlling the thickness of the perpendicular circuit board.

Additionally, the shape of the electrical connection pattern may be configured to have any shape. Thus, an optimum test device may be provided according to a type of test.

Additionally, the perpendicular circuit boards may be simply piled without the need separately align the perpendicular circuit boards. Thus, the processes of manufacturing perpendicular circuit boards are simplified, the costs incurred to manufacture perpendicular circuit boards are reduced, and an electric signal pathway for exactly delivering a signal is made.

Additionally, manufacturing the perpendicular circuit boards does not separately include a soldering process or a welding process unlike conventional electrode-type and wire-type rubber sockets. Thus, the end portion of a rubber socket is not pushed inward, thereby making it possible to increase the lifespan of the rubber socket, improve the design of the rubber socket and prevent damage to a semiconductor chip during the process of testing the semiconductor chip.

Additionally, the perpendicular circuit board includes a thin buffer film for blocking the rubber substrate from being excessively elastic or deformed so as to protect the electrical connection pattern.

### BRIEF DESCRIPTION OF THE DRAWINGS

FIG. 1 is a sectional view illustrating a method for testing a semiconductor chip on a test stage with a rubber socket according to an embodiment of the present invention.

FIG. 2 is a sectional view illustrating the rubber socket in FIG. 1.

FIG. 3 is an exploded perspective view illustrating the rubber socket in FIG. 2.

FIG. 4 is a sectional view illustrating portion A in FIG. 2.

FIG. 5 is a sectional view illustrating a method for manufacturing the rubber socket in FIG. 2.

FIG. 6 is a sectional view illustrating a method for manufacturing a rubber socket according to another embodiment of the present invention.

FIG. 7 is an exploded perspective view illustrating a rubber socket according to another embodiment of the present invention.

FIG. 8 is a sectional view illustrating rubber socket according to another embodiment of the present invention.

FIG. 9 is a sectional view illustrating a method for manufacturing the rubber socket in FIG. 8.

FIG. 10 a sectional view illustrating a rubber socket according to yet another embodiment of the present invention.

FIG. 11 is an exploded perspective view illustrating the rubber socket in FIG. 10.

FIG. 12 is a sectional view illustrating the electrical connection member FIG. 11.

FIGS. 13 to 17 are sectional views illustrating a method for manufacturing the rubber socket in FIG. 10.

FIG. 18 is a sectional view illustrating a method for testing a semiconductor chip on a test stage with a rubber socket according to an embodiment of the present invention.

FIG. 19 sectional view illustrating the rubber socket in FIG. 18.

FIG. 20 is a sectional view illustrating the perpendicular circuit board in FIG. 19.

FIG. 21 is a side view illustrating the perpendicular circuit board in FIG. 20.

FIG. 22 is a perspective view illustrating the perpendicular circuit board in FIG. 20.

FIG. 23 is a sectional view illustrating a perpendicular circuit board according to another embodiment of the present invention.

FIG. 24 is a perspective view illustrating the perpendicular circuit board in FIG. 23.

FIGS. 25 to 28 are perspective views illustrating a method for manufacturing the perpendicular circuit board in FIG. 23.

FIG. 29 is a sectional view illustrating a perpendicular circuit board according to yet another embodiment of the present invention.

FIG. 30 is a sectional view illustrating a method for testing a semiconductor chip on a test stage with a rubber socket according to yet embodiment of the present invention.

### BEST MODE FOR CARRYING OUT THE INVENTION

Description of the specific structure or function of the invention is provided only to describe embodiment of the present invention set forth herein. The inventive subject matter, however, may be embodied in various different forms and should not be construed as being limited to the illustrated embodiments.

The present invention may be modified in various ways and may have many different forms. Thus, specific embodiments will be illustrated in the attached drawings and will be described in this specification. The present invention, however, should not be construed as being limited to the specific embodiments. Rather, the embodiments are intended to cover various modifications, equivalents and replacements within the spirit and technical scope of the present invention. Additionally, like reference numerals denote like components throughout the attached drawings.

It should be understood that, although the terms “first”, “second” etc. may be used herein to describe various components, the components are not limited to the terms. These terms are only used to distinguish one component from another component. For instance, a first component may be referred to as a second component and similarly, a second component may also be referred to as a first component without departing from the scope of the right to the present invention.

It should be understood that when one component is referred to as “connecting to” or “contacting” another component, can directly connect to or contact another component, or a third component may exist between one component and another component. In contrast, when one component is referred to as “directly connecting to” or “directly contacting” another component, there is no third component between one component and another component. Descriptions of a spatial relation between components such as “between” and “directly between” or “adjacent to” and “directly adjacent to” etc. should be interpreted likewise.

The terms in this specification are used only to describe specific embodiments. Thus, it should be understood that the terms are not intended to limit the present invention. The singular forms “a”, “an” and “the” are intended to include the plural forms as well, unless explicitly indicated otherwise. It should be further understood that the terms “comprise” or “have,” when used in this specification, specify the presence of stated features, integers, steps, operations, components, parts or a combination thereof but do not mean precluding the presence or addition of one or more other features, integers, steps, operations, components, parts or a combination thereof.

Unless otherwise defined, all the terms including technical or scientific terms used herein have the same meaning as commonly understood by a person having ordinary skill in the art to which the present invention pertains. Further, terms such as those defined in commonly used dictionaries should be interpreted as having a meaning that is consistent with their meaning in the context of the relevant art and should not be interpreted in an idealized or overly formal sense unless explicitly so defined herein.

Below, preferred embodiments of the invention will be specifically described with reference to the attached drawings. Throughout the drawings, like reference numerals denote like components, and like components will not be repeatedly described.

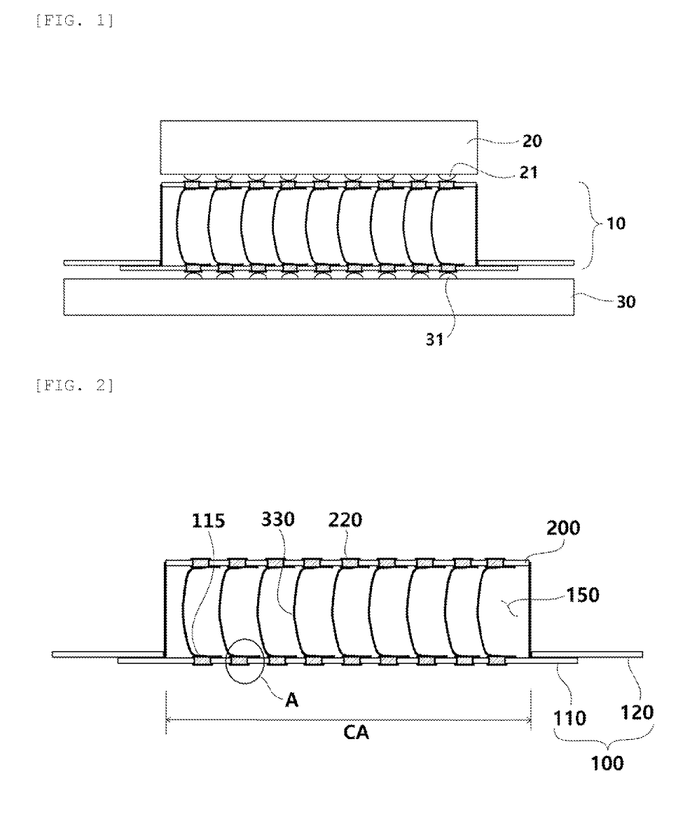

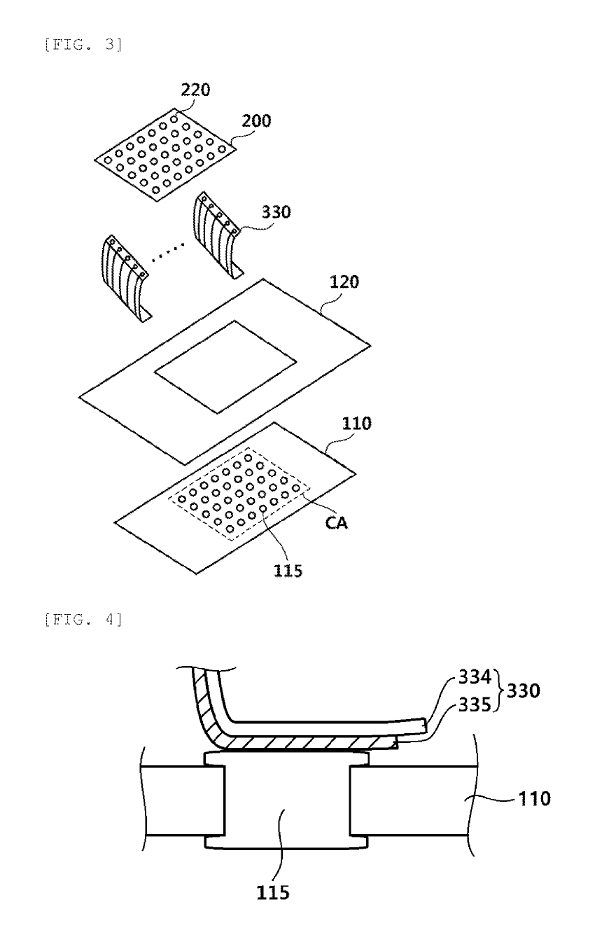

FIG. 1 is a sectional view illustrating a method for testing a semiconductor chip on a test stage with a rubber socket according to an embodiment of the present invention, FIG. 2 is a sectional view illustrating the rubber socket in FIG. 1, and FIG. 3 is exploded perspective view illustrating the rubber socket in FIG. 2.

With reference to FIGS. 1 to 3, a semiconductor chip 20 is disposed on a rubber socket 10. Electrode pads 21 on the semiconductor chip 20 contact an upper electrode part 220 disposed and exposed on the upper surface of the rubber socket 10.

A stage 30 is disposed at the lower portion of a lower film assembly 100. For instance, the stage 30 may be configured as a stage for testing semiconductor chips 20. A lower electrode part 115, exposed on the lower portion of a lower film 110, contacts electrode pads 31 of the stage 30.

When the semiconductor chip 20 is pressed toward the stage 30, the electrode pads 21 of the semiconductor chip 20 are electrically connected to the stage electrode pads 31 of the stage 30 through the rubber socket 10.

The semiconductor chip is tested by means of a test signal supplied through the stage electrode pads 31 of the stage.

The rubber socket 10 includes a lower film assembly 100, a rubber layer 150, an upper film 200, an electrical connection member 330.

The lower film assembly 100 includes a lower film 110 and a film guide 120.

The lower film 110 includes a plurality of lower electrode parts 115 coupled to a thin synthetic resin film. For instance, the lower film 110 may be 20 μm to 100 μm thick. In this embodiment, the lower film 110 may include a synthetic resin such as polyimide, polyvinyl, polypropylene, polycarbonate, FR4, PVC etc.

The upper surface of the lower electrode parts 115 is coupled to an electrical connection pattern 335 of the electrical connection member 330. In this embodiment, each of the lower electrode parts 115 may be configured to pass through the lower film 110 such that the lower surface of the lower electrode parts contacts the electrode pads 31 of the stage 30. In this case, the upper surface of the lower electrode parts 115 and the electrical connection pattern 335 are integrally formed by means of a thermal ultrasonic bonding method, a soldering method etc. while the lower surface of the lower electrode parts 115 may be laid and disposed on the electrode pads 31.

The film guide 120 has a plane shape and is integrally formed on the lower film 110 so as to guide the lower film 110 and make the same have a flat shape. The film guide 120 is disposed at an area peripheral to the lower film 110. In this embodiment, the film guide 120 may include a metallic plate or a synthetic resin such as polyimide, polyvinyl, polypropylene, polycarbonate, FR4, PVC etc. For instance, the film guide 120 may be 0.1 t to 0.5 t thick.

The upper film 200 includes a plurality of upper electrode parts 220 coupled to a thin synthetic resin film. For instance, the upper film 200 may be 20 μm to 100 μm thick. In this embodiment, the upper film 200 may include a synthetic resin such as polyimide, polyvinyl, polypropylene, polycarbonate, FR4, PVC etc. For instance, the upper film 200 may include a material the same as that of the lower film 110.

The upper film 200 is disposed above the lower film 110 such that the upper film 200 the lower film 110 face each other, and corresponds to the central area (CA) of the lower film 110.

The lower surface of the upper electrode parts 220 is coupled to the electrical connection patterns 335 of the electrical connection member 330. In this embodiment, each of the upper electrode parts 220 may be configured to pass through the upper film 200 such that the upper surface of the upper electrode parts contacts the electrode pads 21 of the semiconductor chip 20. In this case, the lower surface of the upper electrode parts 220 and the electrical connection pattern 335 are integrally formed by means of a thermal ultrasonic bonding method, a soldering method etc. while the electrode pads 21 of the semiconductor chip 20 may be laid and disposed on the upper surface of the upper electrode parts 220.

The rubber layer 150 is disposed between the central area (CA) of the lower film 110 and the upper film 200 so as to constantly maintain the gap between the lower film 110 and the upper film 200.

The rubber layer 150 may include an elastic material such as a silicone resin, synthetic rubber etc. When an external force is applied on the upper film 200, the rubber layer 150 is compressed and resists the external force. Additionally, even when a semiconductor chip 20 having an irregular shape is disposed on the upper film 200, stable electrical bonding may be accomplished because of the compression of the rubber layer 150. In another embodiment, a rubber layer 150 may be omitted because the electrical connection member 330 has enough stiffness and elasticity.

FIG. 4 is a sectional view Illustrating portion A in FIG. 2. In this embodiment, the structure of the connection between the electrical connection member and the upper electrode part the same as the structure of the connection between the electrical connection member and the lower electrode part. The structure of the connection between the electrical connection member and the lower electrode part will be exemplarily described so as to be simply explained. With reference to FIGS. 1 to 4, the electrical connection member 330 is physically connected with the lower electrode part 115 and the upper electrode part 220.

The lower electrode part 115 includes a conductive patter exposed on the upper surface and the lower surface of the lower film 110. The conductive pattern exposed on the upper surface of the lower electrode part 115 is physically connected with the electrical connection pattern 335 of the electrical connection member 330. The upper surface of the lower electrode part 115 and the electrical connection pattern 335 may be coupled by means of thermal compression using ultrasonic bonding or means of soldering.

For instance, the lower electrode part 115 and the electrical connection pattern 335 may be welded by means of thermal compression using ultrasonic bonding. When the lower electrode part 115 and the electrical connection pattern 335 are welded by means of thermal compression using ultrasonic bonding, the lower electrode part 115 and the electrical connection pattern 335 may include gold, copper etc.

In another embodiment, when a lower electrode part 115 and an electrical connection pattern 335 are coupled by means of soldering, soldering is performed on a film on which liquid solder paste screen-printed (e.g. blind via-type film) using heat or lasers such that the lower electrode part 115 may be coupled to the electrical connection pattern 335. Soldering may include tin, lead, gold, silver alloy, copper, aluminum, nickel, rhodium and an alloy thereof.

With reference to FIGS. 1 to 3, the upper electrode part 220 includes a conductive patter exposed on the upper surface and the lower surface of the upper film 200. The conductive pattern protruding from the lower surface of the upper electrode part 220 is physically connected with the electrical connection pattern 335 of the electrical connection member 330. The lower surface of the upper electrode part 220 and the electrical connection pattern 335 may be coupled by means of thermal compression using ultrasonic bonding or by means of soldering. For instance, the electrical connection pattern 335 may be coupled with the lower electrode part 115 and the upper electrode part 220 by means of the same sort of thermal compression. In another embodiment, an electrical connection pattern 335 may be coupled to any one of the lower electrode part 115 and the upper electrode part 220 by means of thermal compression using ultrasonic bonding and may be coupled to the rest by means of soldering.

The electrical connection member 330 passes through the rubber layer 150 and electrically connects the lower electrode part 115 and the upper electrode part 220. The electrical connection member 330 includes a soft substrate 334 and the electrical connection pattern 335.

The soft substrate 334 has a flat plate shape and is easily bent by an external force. For instance, the soft substrate 334 may include a synthetic resin such as polyimide, polyvinyl, polypropylene, polycarbonate, FR4, PVC etc.

A plurality of electrical connection patterns 335 are vertically formed on one lateral surface of the soft substrate 334. In this embodiment, plurality of electrical connection patterns 335 may be regularly spaced apart from each other and arranged in parallel on the soft substrate 334. In another embodiment, the gap of the coupling between a plurality of electrical connection patterns 335 and a lower electrode part 115, and the gap of the coupling between a plurality of electrical connection patterns 335 and an upper electrode part 220 may be different. In yet another embodiment, some of the plurality of electrical connection patterns 335 are electrically connected, and the number of the lower electrode parts 115 connected to the lower portion of the electrical connection member 330 may differ from the number of the upper electrode parts 220 connected to the upper portion of the electrical connection member 330.

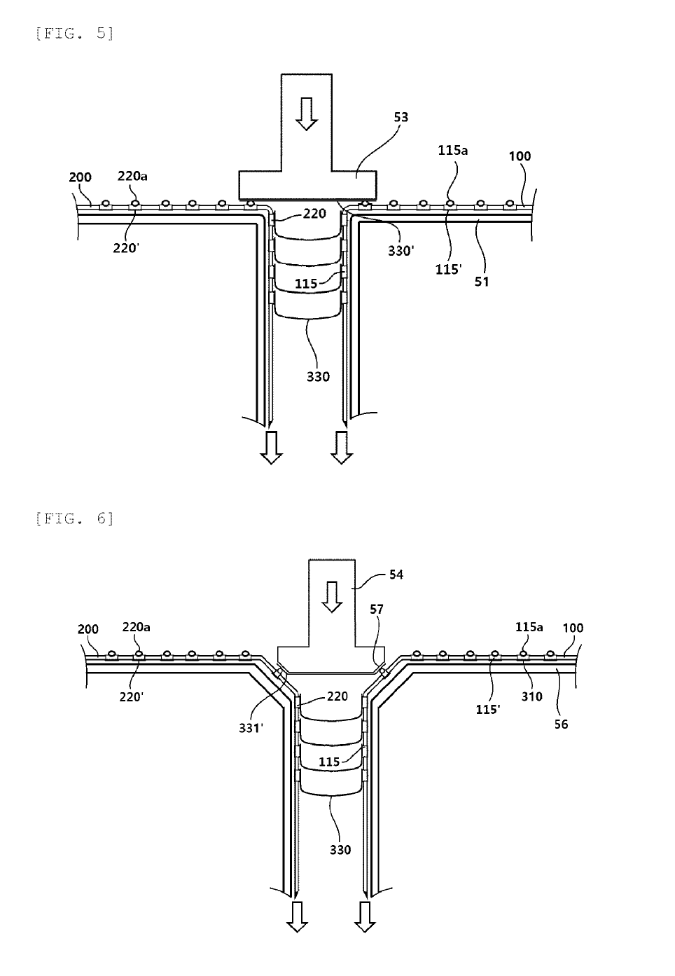

FIG. 5 is a sectional view illustrating a method for manufacturing the rubber socket in FIG. 2.

With reference to FIGS. 1 to 5, primitive lower electrode parts 115′ and primitive upper electrode parts 220′ are formed in the central areas (CA) of a lower film 100 and an upper film 200.

Lower joint parts 115a are formed at the upper portions of the primitive lower electrode parts 115′. The lower joint parts 115a are configured to protrude from the upper surface of the primitive lower electrode parts 115′. In this embodiment, the lower joint parts 115a include the same material as the primitive lower electrode parts 115′. In another embodiment, lower joint parts 115a may include a metal having a melting point lower than that of the primitive lower electrode parts 115′ such that the following thermal compression using ultrasonic bonding may be easily performed.

Upper joint parts 220a are formed at the upper portions of the primitive upper electrode parts 220′. The upper joint parts 220a are configured to protrude from the upper surface of the primitive upper electrode parts 220′. In this embodiment, the upper joint parts 220a include the same material as the primitive upper electrode parts 220′. In another embodiment, upper joint parts 220a may include a metal having a melting point lower than that of the primitive upper electrode parts 270′ such that the following thermal compression using ultrasonic bonding may be easily performed.

For instance, the lower joint parts 115a and upper joint parts 220a may include a gold bump. When including a gold bump, the lower joint parts 115a and upper joint parts 220a are not easily joined by means of usual soldering. Thus, thermal compression using ultrasonic bonding is used.

Next, an electrical connection member 330′ is disposed on the lower surface of a thermal compression member 53 such that an electrical connection pattern 335 faces downward.

Then the thermal compression member 53 is moved downward, and the lower surface of the electrical connection pattern 335 is pressed toward the lower Joint part 115a and upper joint part 220a.

Next, ultrasonic waves and heat are supplied between the electrical connection pattern 335 and the lower joint part 115a and between the electrical connection pattern 335 and the upper joint part 220a by means of the thermal compression member 53 so as to weld both ends of the electrical connection member 335 to the lower joint part 115a and upper joint part 220a. When both ends of the electrical connection member 335 are welded to the lower joint part 115a and upper joint part 220a, the electrical connection pattern 330 is solidly coupled to the lower electrode part 115 and upper electrode part 220.

Next, with reference to FIGS. 2 to 3, a rubber layer 150 is formed between the lower film 110 and the upper film 200 so as to constantly maintain the gap between a lower film assembly 100 and the upper film 200.

Finally, a film guide 120 is coupled or the lower film 110 so as to form the lower film assembly 100. In another embodiment, a lower film assembly 100 may be formed before the rubber layer 150 is formed.

According to the above-described embodiment, the electrical connection member 330 is used instead of a wire so as to connect the lower electrode parts 115 of the lower film 110 and the upper electrode parts 220 of the upper film 200. In this case, the upper portion of the electrical connection member 330 is connected in parallel to the lower surface of the upper electrode part 220, the lower portion of the electrical connection member 330 is connected in parallel to the upper surface of the lower electrode part 115, and the central portion of the electrical connection member 330 is connected to the upper electrode part 220 and lower electrode part 115 in the state where the central portion of the electrical connection member is perpendicularly curved between the upper electrode part and lower electrode part.

When the electrical connection member 330 includes a soft substrate 334 and an electrical connection pattern 335, external pressure may be effectively dispersed in the case in which an external shock is applied and a semiconductor chip is repeatedly tested.

Additionally, the width of the electrical connection pattern 335 formed on the soft substrate 334 may be controlled such that the surface are of the electrical connection pattern 335 is expanded, thereby reducing resistance.

Additionally, the electrical connection pattern 335 and the soft substrate 334 are integrally formed so as to prevent the electrical connection pattern 335 from being cut, thereby making it possible to increase the lifespan of a rubber socket 10 and improve the credibility of the same.

FIG. 6 is a sectional view illustrating a method for manufacturing a rubber socket according to another embodiment of the present invention. In this embodiment, components except for an incline compression part 57 are the same as those of the embodiment illustrated in FIG. 5. Thus, description of the same components will be omitted.

With reference to FIGS. 2, 3 and 6, primitive lower electrode parts 115′ and primitive upper electrode parts 220′ are formed in the central areas (CA) of a lower film 100 and an upper film 200 in order for a rubber socket to ne manufactured.

Next, lower joint parts 115a are formed at the upper portions of the primitive lower electrode parts 115 while upper joint parts 220a are formed at the upper portions of the primitive upper electrode parts 220.

Next, an electrical connection member 330′ is disposed on the lower surface of a thermal compression member 53 such that an electrical connection pattern 335 faces downward.

In this embodiment, the thermal compression member 54 includes an incline compression part an electrical connection member 331′ is attached to the end of the lower side of the incline compression part 57 and the thermal compression member 54 along the inclined direction thereof, and the thermal compression member 54 heats and compresses the electrical connection member 331′ with respect to lower joint parts 115a and upper joint parts 220a arranged in an inclined direction.

Next, a rubber layer 150 is formed between the lower film 110 and the upper film 200 so as to constantly maintain the gap between a lower film assembly 100 and the upper film 200.

Finally, a film guide 120 is coupled on the lower film 110 so as to form the lower film assembly 100.

According to the above-described embodiment, the thermal compression member 54 includes the incline compression part 57 and heats and compresses the electrical connection member 33l with respect to the lower joint parts 115a and upper joint parts 220a arranged in an inclined direction so as to solid couple the electrical connection member 330 to the lower electrode parts 115 and upper electrode parts 220, thereby making it possible to increase the lifespan of a rubber socket 10 and improve the credibility of the same.

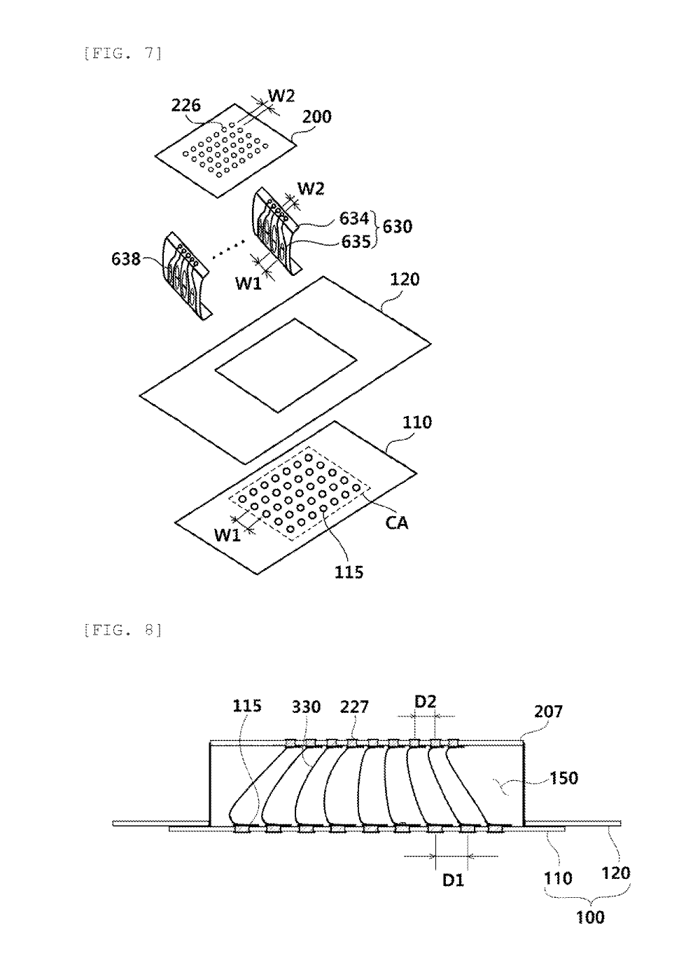

FIG. 7 is an exploded perspective view illustrating a rubber socket according to another embodiment of the present invention. In this embodiment, components except for an upper electrode part and an electrical connection pattern are the same as those of the embodiment illustrated in FIGS. 1 to 4. Thus, description of the same components will be omitted.

With reference to FIG. 7, the distance (W2) between upper electrode parts 226 of an upper film 200 is shorter than the distance (W1) between lower electrode parts 115 of a lower film 110.

An electrical connection member 630 includes a soft substrate 634 and an electrical connection pattern 635.

In each electrical connection member 630 according to this embodiment, the distance between adjacent electrical connection patterns 635 at the upper portions thereof Is different from the distance between adjacent electrical connection patterns at the lower portions thereof. In each electrical connection member 630, the distance (W1) between adjacent electrical connection patterns 635 at the lower portions thereof is the same as the distance (W1) between the lower electrode parts 115, and the distance (W2) between adjacent electrical connection patterns at the upper portions thereof is the same as the distance (W2) between the upper electrode parts 220.

In this embodiment, the electrical connection member 630 may further include central openings 638 which is opened and formed between the electrical connection patterns 635. The central openings 638 are used as a passage into which silicone etc. is injected so as to form a rubber layer 150, and the electrical connection member 630 are configured to be easily deformed by external pressure even when the rubber layer 150 is hardened and has elasticity.

According to the above-described embodiment of the present invention, the density of semiconductor chips (20 in FIG. 1) is improved. Thus, even when the distance between adjacent electrode pads (21 in FIG. 1) of a chip becomes short, the shape of the electrical connection pattern 635 or the gap between attached upper electrode parts 220 is controlled without reducing the distance between stage electrode pads (31 in FIG. 1) of a stage (30 in FIG. 1) such that a test may be easily performed.

FIG. 8 is a sectional view illustrating a rubber socket according to another embodiment of the present invention. In this embodiment, components except for an upper electrode part are the same as those of the embodiment illustrated in FIGS. 1 to 4. Thus, description of the same components will be omitted.

With reference to FIG. 8, a rubber socket 10 includes a lower film assembly 100, a rubber layer 150, an upper film 207, and an electrical connection member 330.

The upper film 207 includes a plurality of upper electrode parts 227 coupled to a thin synthetic resin film. The distance (D2) between upper electrode parts 227 of an upper film 207 is shorter than the distance (D1) between lower electrode parts 115 of a lower film 110.

In this embodiment, the distance between adjacent electrical connection members 330 at the portions thereof is different from the distance D1 between adjacent electrical connection members at the lower portions thereof. The distance (D1) between adjacent electrical connection members 330 at the lower portions thereof is the same as the distance (D1) between the lower electrode parts 115, and the distance between adjacent electrical connection patterns 330 at the upper portions thereof is the same as the distance (D2) between the upper electrode parts 220.

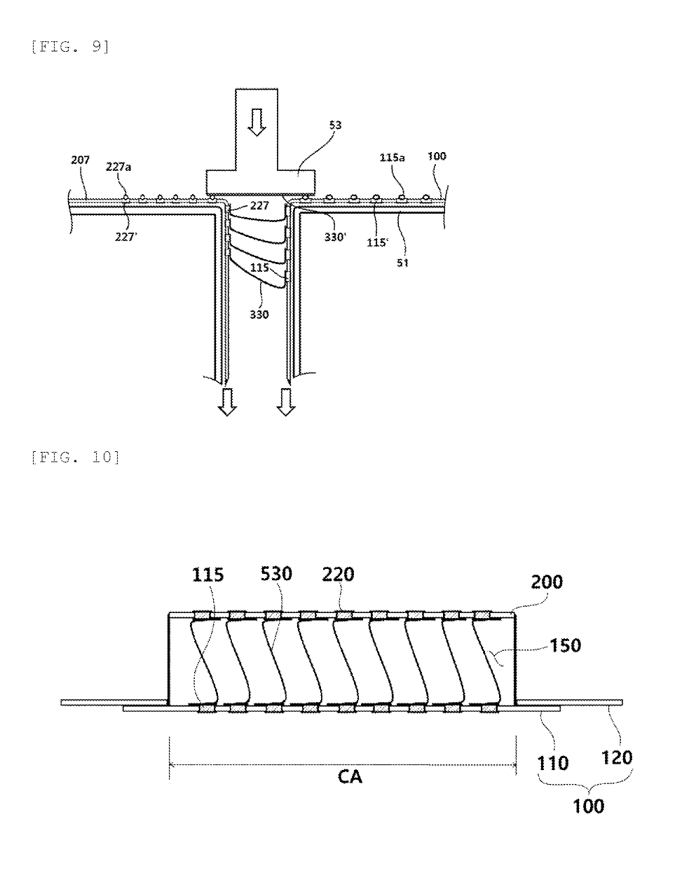

FIG. 9 is a sectional view illustrating a method for manufacturing the rubber socket in FIG. 8.

With reference to FIGS. 8 and 9, primitive lower electrode parts 115′ and primitive upper electrode parts 227′ are formed in the central areas (CA) of a lower film 100 and an upper film 200 in order for a rubber socket to be manufactured.

Next, lower joint parts 115a are formed at the upper portions of the primitive lower electrode parts 115′ while upper joint parts 227a are formed at the upper portions of the primitive upper electrode parts 227′.

Next, an electrical connection member 330′ is disposed on the lower surface of a thermal compression member 53 such that an electrical connection pattern faces downward.

Then the thermal compression member 53 heats and compresses the electrical connection member 330′ with respect to lower joint parts 115a and upper joint parts 227a arranged in an inclined direction.

Next, a rubber layer 150 is formed between the lower film 110 and the upper film 207 so as to constantly maintain the gap between a lower film assembly 100 and the upper film 207.

Finally, a film guide 120 is coupled on the lower film 110 so as to form the lower film assembly 100.

In this embodiment, the embodiment in FIG. 7 and the embodiment in FIGS. 8 and 9 are separately illustrated. However, the distance between adjacent electrical connection patterns and the distance between adjacent electrical connection members may be simultaneously changed in each electrical connection member through a combined embodiment of the embodiment in FIG. 7 and the embodiment in FIGS. 8 and 9.

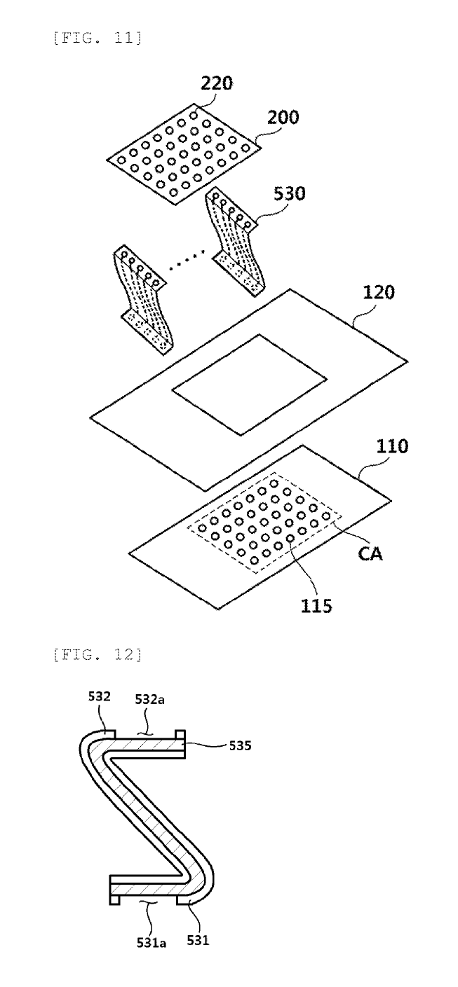

FIG. 10 is a sectional view illustrating a rubber socket according to yet another embodiment of the present invention, and FIG. 11 is an exploded perspective view illustrating the rubber socket in FIG. 10. In this embodiment, components except for an electrical connection member are the same as those of the embodiment illustrated in FIGS. 1 to 4. Thus, description of the same components will be omitted.

With reference to FIGS. 10 to 12, a rubber socket Includes a lower film assembly 100, a rubber layer 150, an upper film 200, and an electrical connection member 530.

The lower film assembly 100 includes a lower film 110 and a film guide 120.

The lower film 110 includes a plurality of lower electrode parts 115 coupled to a thin synthetic resin film.

The upper surface of the lower electrode parts 115 is coupled to the lower surface of an electrical connection pattern 535 of the electrical connection member 530. The upper surface of the lower electrode parts 115 and the lower surface of the electrical connection pattern 535 are integrally formed by means of a thermal ultrasonic bonding method, a soldering method etc.

The film guide 120 has a plane shape and is integrally formed on the lower film 110 so as to guide the lower film 110 and make the same have a flat shape.

The upper film 200 includes a plurality of upper electrode parts 220 coupled to a thin synthetic resin film.

The lower surface of the upper electrode parts 220 is coupled to the upper surface of the connection pattern 535 of the electrical connection member 530, and the lower surface of the upper electrode parts 220 and the upper surface of the electrical connection pattern 535 are integrally formed by means of thermal ultrasonic bonding method, soldering method etc.

The upper film 200 is disposed above the lower film 110 such that the upper film 200 the lower film 110 face each other and corresponds to the central area (CA) of the lower film 110.

The rubber layer 150 is disposed between the central area (CA) of the lower film 110 and the upper film 200 so as to constantly maintain the gap between the lower film 110 and the upper film 200.

FIG. 12 is a sectional view illustrating the electrical connection member in FIG. 11.

With reference to FIGS. 10 to 12, an electrical connection member 530 includes a plurality of electrical connection patterns 535, a lower coating 531 and an upper coating 532. In this embodiment, the electrical connection member 530 has a “Z” shape and includes an upper opening 532a and a lower opening 531a respectively disposed on the upper portion and the lower portion thereof such that the electrical connection patterns 535 are exposed outward through the upper opening 532a and lower opening 531a.

The plurality of electrical connection patterns 535 are vertically arranged in parallel.

The lower coating 531 supports the lower surface of the electrical connection patterns 535 and includes the lower opening 531a which is formed on one side of the lower coating and coupled to lower electrode parts 115. The lower opening 531a exposes part of the lower surface the electrical connection patterns 535.

The upper coating 532 supports the upper surface of the electrical connection patterns 535 and includes the upper opening 532a which is formed on one side of the upper coating and coupled to upper electrode parts 220. The upper opening 532a exposes part of the lower surface of the electrical connection patterns 535.

In this embodiment, the lower opening 531a and the upper opening 532a has a band shape which extends in a direction perpendicular to the direction in which the electrical connection patterns 535 extend. The lower opening 531a is disposed on the opposite side of the upper opening 532a with respect to the electrical connection patterns 535. In another embodiment, a lower coating 531 and an upper coating 532 respectively include a plurality of lower openings 531a and a plurality upper openings 532a, and the lower openings 531a and upper openings 532a may be arranged so as to miss each other with respect to the electrical connection patterns 535.

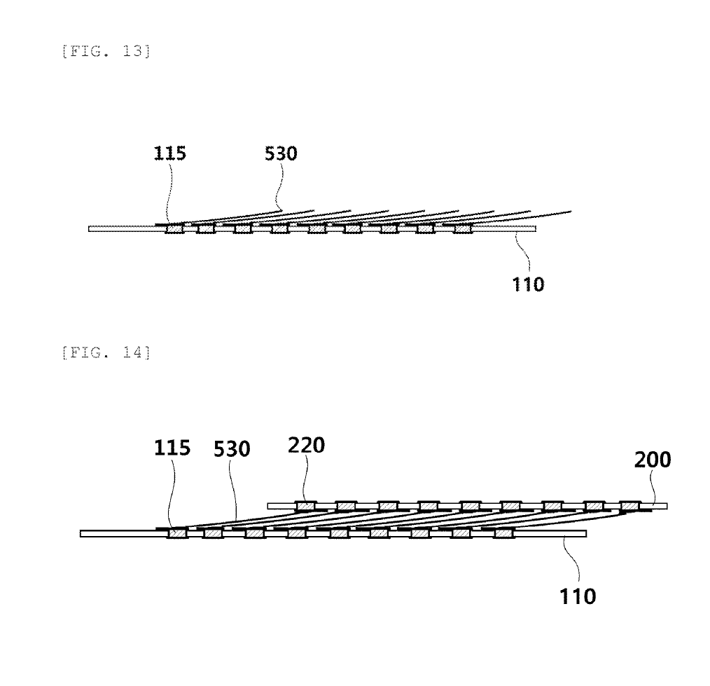

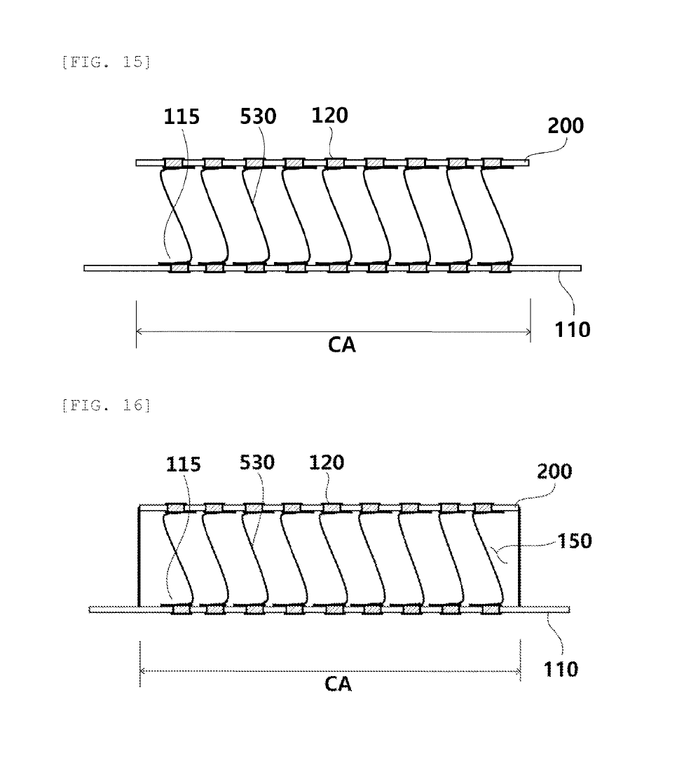

FIGS. 13 to 17 are sectional views illustrating a method for manufacturing the rubber socket in FIG. 10.

With reference to FIGS. 10 to 13, primitive lower electrode parts (115′ in FIG. 5) are formed in the central area (CA) of the lower film 100.

Then lower joint parts (115a in FIG. 5) are formed on the upper portion of the primitive lower electrode parts (115′ in FIG. 5).

Next, a plurality of electrical connection patterns 535 arranged in parallel with each other are formed on a lower coating 531.

Then an upper coating 532 is formed on the lower coating 531 on which the electrical connection patterns 535 are formed.

Next, part of the coating 531 is removed in a direction perpendicular to the direction in which the electrical connection patterns 535 extend, so as to form a lower opening 531a that exposes part of the lower surface of the electrical connection patterns 535.

Next, part of the upper coating 532 is removed in a direction perpendicular to the direction in which the electrical connection patterns 535 extend, so as to form an upper opening 532a that exposes part of the upper surface of the electrical connection patterns 535.

Then the lower surface of the electrical connection patterns 535, exposed through the lower opening 531a, is pressed with respect to the lower joint parts (115a in FIG. 5).

Next, the lower surface of the electrical connection patterns 535 is welded to lower electrode parts 115 by means of thermal compression using ultrasonic bonding.

Next, with reference to FIGS. 10 to 12 and FIG. 14, upper joint parts (220a in FIG. 5) are formed on the upper port on of primitive upper electrode parts (220′ in FIG. 5).

Then an upper film 200 is disposed on the electrical connection members 530, and the upper joint parts (220a in FIG. 5) of the upper film 200 are also arranged on the upper surface of the electrical connection patterns 535.

Next, the upper surface of the electrical connection patterns 535 is attached to upper electrode parts 220 by means of soldering.

Next, the upper film 200 is pushed up and spaced apart from a lower film 110 such that the electrical connection member 530 has a “Z” shape.

Then a rubber layer 150 is formed between the lower film 110 and the upper film 200.

Finally, a film guide 120 is coupled on the lower film 110 so as to form a lower film assembly 100. In another embodiment, a lower film assembly 100 may be formed before a rubber layer 150 is formed.

According to the above-described embodiment, the electrical connection member 530 includes a plurality of electrical connection patterns 535 disposed between an upper coating 532 and a lower coating 531 facing each other and is coupled to one lower electrode part 115 and one upper electrode part 220. In this case, the electrical connection member 530 is solidly coupled to one lower electrode part 115 and one upper electrode part 220 consecutively, compared to an electrical connection member simultaneously coupled to two electrode parts 115, 220.

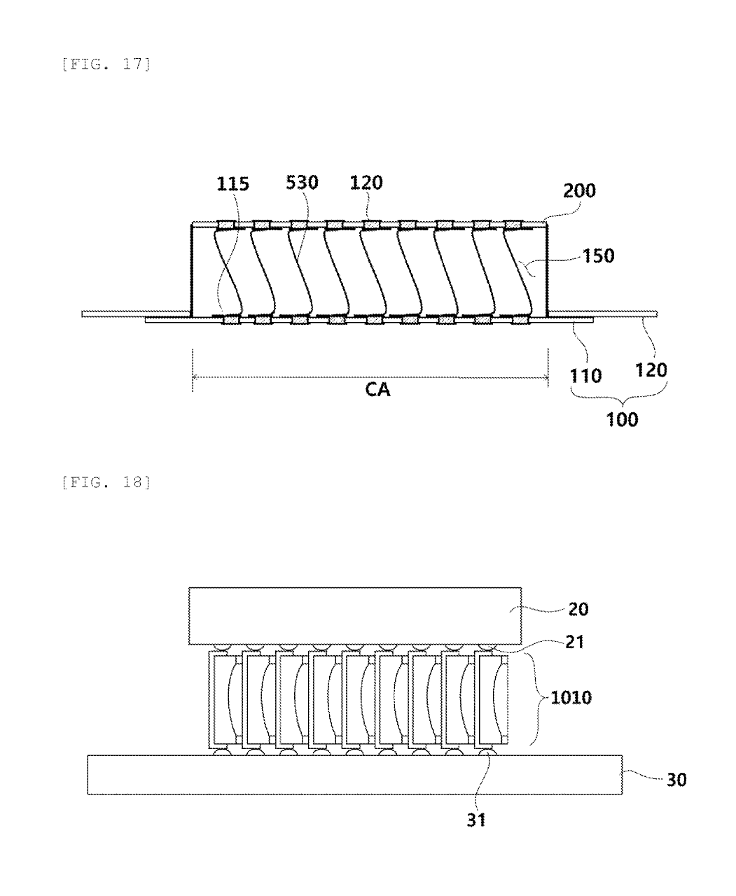

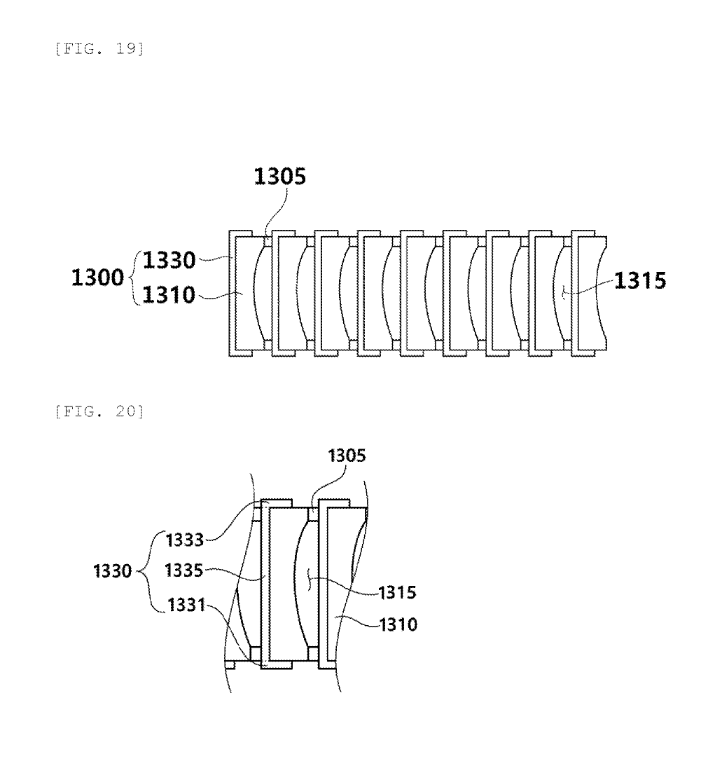

FIG. 18 is a sectional view illustrating a method for testing a semiconductor chip on a test stage with a rubber socket according to an embodiment of the present invention, FIG. 19 is a sectional view illustrating the rubber socket in FIG. 18, and FIG. 20 is a sectional view illustrating the perpendicular circuit board in FIG. 19.

With reference to FIGS. 18 to 20, a semiconductor chip 20 is disposed on a rubber socket 1010. Chip electrode pads 21 of the semiconductor chip 20 contact an upper contact part 1333 disposed and exposed on the upper surface of a rubber socket 1010.

For instance, the stage 30 may be a stage for testing a semiconductor chip 20. A lower contact part 1331 exposed on the lower portion of the rubber socket 10 contacts stage electrode pads 31 of the stage 30.

When the semiconductor chip 20 is pressed toward the stage 30, the chip electrode pads 21 of the semiconductor chip 20 are electrically connected to the stage electrode pads 31 of the stage 30 through the rubber socket 1010.

The semiconductor chip 20 is tested by means of a test signal supplied through the stage electrode pad 31.

The rubber socket 1010 includes a plurality of perpendicular circuit boards 1300 and a plurality of adhesion layers 1305.

The perpendicular circuit boards 1300 are perpendicularly piled with respect to the upper surface of the stage 30 and are connected and integrally configured with adjacent perpendicular circuit boards 1300 thereof by the adhesion layers 1305.

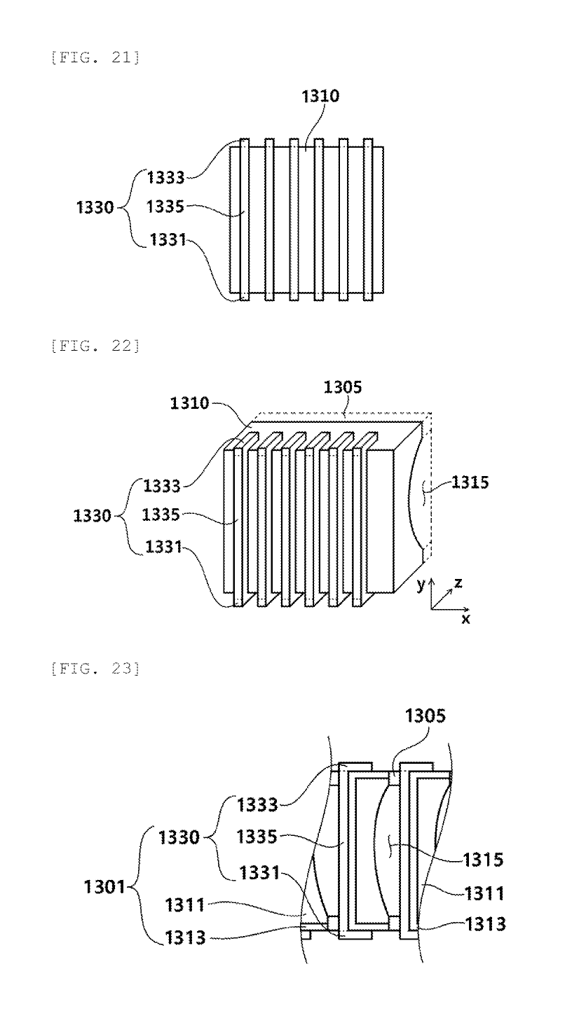

FIG. 21 is a side view illustrating the perpendicular circuit board in FIG. 20, and FIG. 22 is a perspective view illustrating the perpendicular circuit board in FIG. 20.

With reference to FIGS. 18 to 22, each perpendicular circuit board 1300 includes a rubber substrate 1310 and an electrical connection pattern 1330.

The rubber substrate 1310 includes a material such as silicone rubber, resin, synthetic rubber etc., which is temporarily deformed by an external force, and returns to the original shape thereof when the external force is removed.

The rubber substrate 1310 has a rectangular flat plate shape which extends vertically. The rubber substrate 1310 in FIG. 5 has a cuboid shape. However, in FIG. 5, the thickness of the rubber substrate in the Z direction is exaggerated for convenience in illustration. In fact, the thickness of the rubber substrate in the X-axis and Y-axis directions is larger than that of the rubber substrate in the Z-axis direction. Thus, the rubber substrate has a thin flat plate shape. The thickness of the rubber substrate 1310 is smaller than the distance between adjacent chip electrode pads 21. If the thickness of the rubber substrate 1310 is larger than the distance between adjacent chip electrode pads 21, a short circuit may occur between the adjacent chip electrode pads 21.

An electrical connection pattern 1330 covers part of the upper surface, the lateral surface and part of the lower surface of the rubber substrate 1310 and has a long shape that vertically extends.

In this embodiment, a connection part 1335 of the electrical connection pattern 1330 is disposed on one lateral surface of the rubber substrate 1310, and a buffer space 1315 formed on the other side of the rubber substrate 1310.

The buffer space 1315 increases the distance between the other lateral surface of a rubber substrate 1310 and one lateral surface of an adjacent rubber substrate 1310. When perpendicular circuit boards 1300 are pressed by a vertical external force in the process of testing a semiconductor chip 20, the rubber substrate 1310 may be bent. When the distance between the other surface a rubber substrate 1310 and one surface of an adjacent rubber substrate 1310 is increased, a space in which the rubber substrate 1310 may be bent by a vertical external force is provided such that the perpendicular circuit boards 1300 are buffered against the external force.

The electrical connection pattern 1330 includes a lower contact part 1331, an upper contact part 1333 and a connection part 1335.

The lower contact part 1331 is disposed only on part of the lower surface of the rubber substrate 1310, contacts the connection part 1335 and is disposed on the opposite side of the buffer space 1315. In the case in which the Lower contact part 1331 extends to a position adjacent to the buffer space, when the perpendicular circuit boards 1300 are deformed by an external force, a short circuit may occurs in the lower contact parts 1331 of adjacent perpendicular circuit boards 1300. In this embodiment, the lower contact part 1331 is disposed only on part of the lower surface of the rubber substrate 1310. Thus, when the perpendicular circuit boards 1300 are deformed by an external force, a short circuit is prevented from occurring between adjacent lower contact parts 1331.

The upper contact part 1333 is disposed only on part of the upper surface of the rubber substrate 1310, contacts the connection part 1335 and is disposed on the opposite side of the buffer space 1315. In the case in which the upper contact part 1333 extends to a position adjacent to the buffer space, when the perpendicular circuit boards 1300 are deformed by an external force, a short circuit may occurs in the upper contact parts 1333 of adjacent perpendicular circuit boards 1300. In this embodiment, the upper contact part 1333 is disposed only on part of the upper surface of the rubber substrate 1310. Thus, even when the perpendicular circuit boards 1300 are deformed by an external force, a short circuit is prevented from occurring between adjacent upper contact parts 1333.

The connection part is disposed on one lateral surface of the rubber substrate 1310 and connects the lower contact part 1331 and the upper contact part 1333. The connection part 1335 is disposed on the opposite side of the buffer space 1315.

The adjacent perpendicular circuit boards 1300 are physically connected by an adhesion layer 1305.

When a semiconductor chip 20 is tested on a stage 30, a rubber socket 1010 is disposed between the semiconductor chip 20 and the stage 30, and the perpendicular circuit boards 1300 are vertically arranged and disposed between the chip electrode pads 21 of the semiconductor chip 20 and stage electrode pads 31 of the stage 30. The lower contact parts 1331 of the electrical connection patterns 1330 contact the chip electrode pads 21 while the upper contact parts 1333 contact the stage electrode pads 31, such that the stage electrode pads 31 and the chip electrode pads 21 are electrically connected through the perpendicular circuit boards 1300.

In order for a rubber socket 1010 of this embodiment to be manufactured, silicone rubber, synthetic rubber etc. are molded so as to form a flat plate-shaped rubber substrate 1310.

Next, a lower contact part 1331, an upper contact part 1333 and a connection part 1335 are respectively formed on part of the lower surface, part of the upper surface and one lateral surface of a rubber substrate 1310 so as to form a perpendicular circuit board 1300 including a rubber substrate 1310 and an electrical connection pattern 1330. For instance, in order for the electrical connection pattern 1330 to be formed, a metallic film is formed on the surface of the rubber substrate 1310 by means of deposition, plating etc., and the metallic film is patterned by means of an etching process, a laser process, a physical process etc.

Then a plurality of perpendicular circuit boards 1300 are vertically piled such that the lower contact parts 1331 and upper contact parts 1333 are exposed in the upward and downward directions of the rubber substrate.

Next, the perpendicular circuit boards 1300 vertically piled are coupled by means of an adhesion layer 1305 so as to form a rubber substrate 1310.

According to the above-described embodiment of the present invention, a rubber socket 1010 may effectively disperse external pressure using a plurality of perpendicular circuit boards 1300 perpendicularly piled, instead of a wire or a pad, in the case in which an external shock is applied and a semiconductor chip 20 is repeatedly tested.

Additionally, the width of the electrical connection pattern 1330 of the perpendicular circuit board 1300 may be controlled such that the surface are of the electrical connection pattern 1330 is expanded, thereby reducing resistance.

Additionally, the electrical connection pattern 1330 and the perpendicular circuit board 1300 are integrally formed so as to prevent the electrical connection pattern 1330 from being cut, thereby making it possible to increase the lifespan of a rubber socket 1010 and improve the credibility of the same.

Additionally, the perpendicular circuit boards 1300 may be simply piled without the need to separately align the perpendicular circuit boards. Thus, the processes of manufacturing perpendicular circuit boards are simplified, the costs incurred to manufacture perpendicular circuit boards are reduced, and an electric signal pathway for exactly delivering a signal is made.

Additionally, manufacturing the perpendicular circuit boards does not separately include a soldering process or a welding process unlike conventional electrode-type and wire-type rubber sockets. Thus, the end portion of a rubber socket is not pushed inward, thereby making it possible to increase the lifespan of the rubber socket, improve the design of the rubber socket and prevent damage to a semiconductor chip 20 during the process of testing the semiconductor chip.

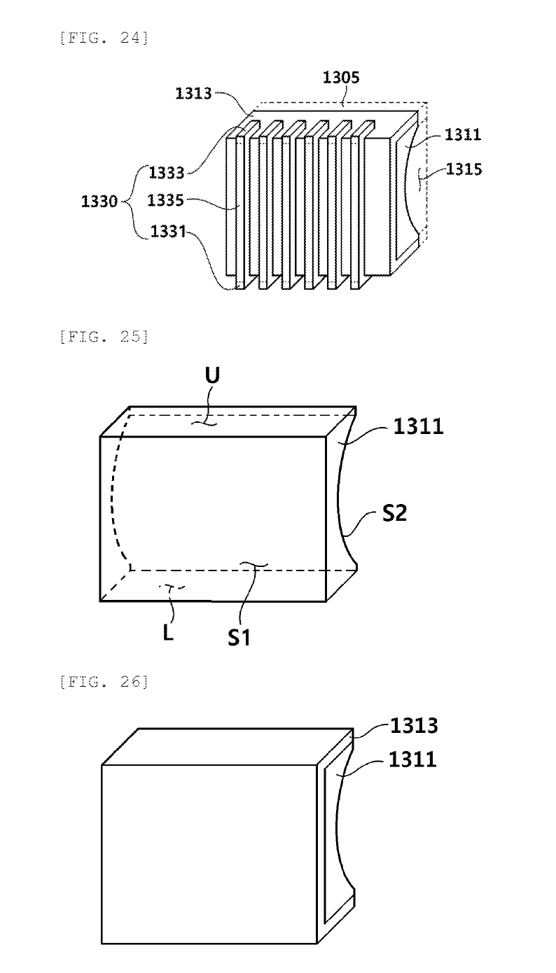

FIG. 23 is a sectional view illustrating a perpendicular circuit board according to another embodiment of the present invention, and FIG. 24 is a perspective view illustrating the perpendicular circuit board in FIG. 23. In this embodiment, components except for a thin buffer film are the same as those of the embodiment illustrated in FIGS. 18 to 22. Thus, description of the same components will be omitted.

With reference to FIGS. 18, 23 and 24, a rubber socket is disposed between a semiconductor chip 20 and a stage 30 and electrically connects chip electrode pads f the semiconductor chip 20 and stage electrode pads 31 of the stage 30.

The rubber socket includes a plurality of perpendicular circuit boards 1301 and a plurality of adhesion layers 1305.

The perpendicular circuit boards 1301 are perpendicularly piled with respect to the upper surface of the stage 30 and are connected and integrally configured with adjacent perpendicular circuit boards 1301 thereof by the adhesion layers 1305.

Each perpendicular circuit board 1301 includes a rubber substrate 1311, a thin buffer film 1313, and an electrical connection pattern 1330.

The rubber substrate 1311 includes a material such as silicone rubber, resin, synthetic rubber etc., which is temporarily deformed by an external fore and returns to the original shape thereof when the external force is removed.

The thin buffer film 1313 is disposed on one lateral surface, upper surface and surface of the rubber substrate 1311. For instance, the thin buffer film 1313 may be disposed between the rubber substrate 1311 and the electrical connection patterns 1330.

The thin buffer film 1313 may include a synthetic resin such as polyimide, polyvinyl, polypropylene, polycarbonate, FR4, PVC etc. The thin buffer film 1313 includes a material that can strongly adhere to the electrical connection pattern 1330 and has a lower deformation level than the rubber substrate 1311 with respect to the same external force.

The thin buffer film 1313 is less thick than the rubber substrate 1311. In this embodiment, the thin buffer film 1313 may be 10 μm to 200 μm thick. When the thin buffer film 1313 is very thin, the thin buffer film may be torn during the process in which the rubber substrate 1313 is deformed. On the contrary, when the thin buffer film 1313 is very thick, the thin buffer film may prevent the rubber substrate 1313 from being deformed while interfering the buffering operation of the rubber socket unable. For instance, the thin buffer film 1313 may be 20 μm to 100 μm thick.

The thin buffer film 1313 blocks the rubber substrate 1311 from being excessively elastic or deformed so as to protect the electrical connection pattern 1330.

In this embodiment, the thin buffer film 1313 is disposed on one lateral surface of the rubber substrate 1311, and a buffer space 1315 is formed on the other lateral surface of the rubber substrate.

The electrical connection pattern 1330 is disposed on the thin buffer film 1313. In this embodiment, a plurality of electrical connection patterns 1330 are vertically arranged on the thin buffer film 1313 in parallel with each other.

The electrical connection pattern 1330 includes a lower contact part 1331, an upper contact part 1333 and a connection part 1335.

The lower contact part 1331 is disposed only on part of the lower surface of the thin buffer film 1313, contacts the connection part 1335 and is disposed on the opposite side of the buffer space 1315.

The upper contact part 1333 is disposed only on part of the upper surface of the thin buffer film 1313, contacts the connection part 1335 and is disposed on the opposite side of the buffer space 1315.

The connection part 1335 is disposed on one lateral surface of the thin buffer film 1313 and connects the lower contact part 1331 and the upper contact part 1333.

Adjacent perpendicular circuit boards 1301 are physically connected by means of an adhesion layer 1305.

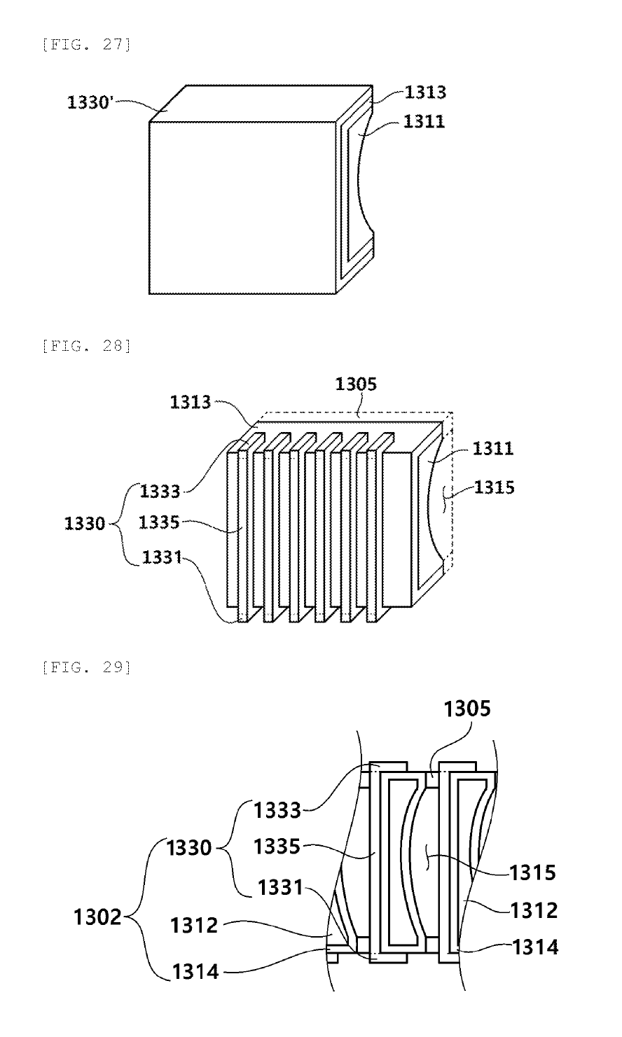

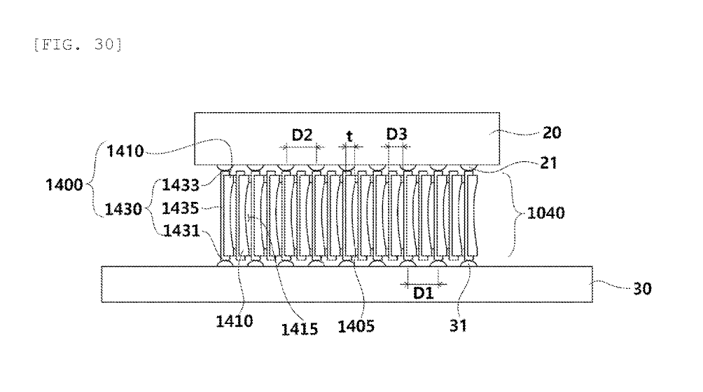

FIGS. 25 to 28 are perspective views illustrating a method for manufacturing the perpendicular circuit board in FIG. 23.

In order for a rubber socket to he manufactured, with reference to FIGS. 23 to 25, silicone rubber, synthetic rubber etc. is molded so as to form a flat plate-shaped rubber substrate 1311. In this embodiment, silicone rubber, synthetic rubber etc. are molded through molding, forming and cutting processes etc. so as to have a desired pitch, and a designed thickness and size. For instance, liquid-phase silicone or solid-phase silicone is injected into a metallic mold so as to form a rubber substrate 1311 including silicone rubber.

One lateral surface (S1) of the rubber substrate 1311 has a flat plate shape, the other lateral surface (S2) has a concave shape, and the upper (U) and lower (L) surfaces have a long shape which has a narrow width and extends.

Next, with reference to FIGS. 23 to 26, a thin buffer film 1313 is formed on the lower surface, upper surface and one lateral surface of the rubber substrate 1311. In this embodiment, a spray coating method, a dipping method, a dry coating method etc. is used to form the thin buffer film 1313.

With reference to FIGS. 23, 24 and 27, a conductive layer 1330′ is formed on the thin buffer film 1313. In this embodiment, gold, silver, copper, aluminum, nickel, rhodium, an alloy thereof etc. may be disposed or plated on the thin buffer film 1313 so as to form a conductive layer 1330′. In another embodiment, a metallic oxide such as ITO, TO, ZO etc. may also be disposed on the thin buffer film 1313 so as to form a conductive layer 1330′.

With reference to FIGS. 23, 24 and 28, the conductive layer 1330′ is patterned so as to form electrical connection patterns 1330 including a lower contact part 1331, an upper contact part 1333 and a connection part 1335. In this embodiment, the conductive layer 1330′ is patterned through masking, etching or a direct laser so as to correspond to the shape of electrical connection patterns 1330, and electrical connection patterns 1330 with a vertical stripe shape are formed on the surface the conductive layer 1330′.

Accordingly, a perpendicular circuit board 1301 including the rubber substrate 1311, the thin buffer film 1313 and the electrical connection pattern 1330 is formed.

Next, a plurality of perpendicular circuit boards 1301 are vertically piled such that the lower contact parts 1331 and upper contact parts 1333 are exposed in the upward and downward directions thereof.

Next, the perpendicular circuit boards 1301 perpendicularly piled are coupled by means of an adhesion layer 1305 so as to complete a rubber substrate.

According to the above-described embodiment of the present invention, the perpendicular circuit board 1301 includes a thin buffer film 1313 for blocking the rubber substrate 1311 from being excessively elastic or deformed so as to protect the electrical connection pattern 1330.

FIG. 29 is a sectional view illustrating a perpendicular circuit board according to yet another embodiment of the present invention. In this embodiment, components except for a thin buffer film are the same as those of the embodiment illustrated in FIGS. 23 to 28. Thus, description of the same components will be omitted.

With reference to FIGS. 18 and 29, a rubber socket disposed between a semiconductor chip 20 and a stage 30 and electrically connects chip electrode pads 21 of the semiconductor chip 20 and stage electrode pads 31 of the stage 30.

The rubber socket includes a plurality of perpendicular circuit boards 1302 and a plurality of adhesion layers 1305.

Each perpendicular circuit board 1302 includes a rubber substrate 1312, a thin buffer film 1314, and an electrical connection pattern 1330.

The rubber substrate 1312 has one side having a flat plate shape and the other side which is bent inward so as to have a buffer space 1315, and has a flat plate shape that extends vertically.

The thin buffer film 1314 is disposed on one lateral surface, the other lateral surface, the upper surface and the lower surface of the rubber substrate 1312.

The thin buffer film 1314 is thinner than the rubber substrate 1312.

The electrical connection pattern 1330 is disposed on the thin buffer film 1314. In this embodiment, a plurality of electrical connection patterns 1330 are vertically disposed on the thin buffer film 1314 in parallel with each other.

The electrical connection pattern 1330 includes a lower contact part 1331, an upper contact part 1333 and a connection part 1335.

The lower contact part 1331 is disposed only on part of the lower surface of the thin buffer film 1314, contacts the connection part 1335 and is disposed on the opposite side of the buffer space 1315.

The upper contact part 1333 is disposed only on part of the upper surface of the thin buffer film 1314, contacts the connection part 1335 and is disposed on the opposite side of the buffer space 1315.

The connection part 1335 is disposed on one lateral surface of the thin buffer film 1314 and connects the lower contact part 1331 and the upper contact part 1333.

Adjacent perpendicular circuit boards 1302 are physically connected by means of the adhesion layer 1305.

In order for a rubber socket according to an embodiment of the present invention to be manufactured, silicone rubber, synthetic rubber etc. is molded so as to form a flat plate-shaped rubber substrate 1312.

Next, a thin buffer film 1314 is formed on one lateral surface, the other lateral surface, the lower surface and the upper surface of the rubber substrate 1312.

Then a conductive layer is formed on one lateral surface, the lower surface and the upper surface of the thin buffer film 1314. In another embodiment, a conductive layer may be formed on one lateral surface, the other lateral surface, the lower surface and the upper surface of the thin buffer film 1314.

Next, the conductive layer is patterned so as to form electrical connection patterns 1330 including a lower contact part 1331, an upper contact part 1333 and a connection part 1335.

Accordingly, a perpendicular circuit board 1302 including the rubber substrate 1312, the thin buffer film 1314 and the electrical connection pattern 1330 is formed.

Next, a plurality of perpendicular circuit boards 1302 are vertically piled such that the lower contact parts 1331 and upper contact parts 1333 are exposed in the upward and downward directions thereof.

Next, the perpendicular circuit boards perpendicularly piled are coupled by means of an adhesion layer 1305 so as to complete a rubber substrate.

FIG. 30 is a sectional view illustrating a method for testing a semiconductor chip on a test stage with a rubber socket according to yet embodiment of the present invention. In this embodiment, components except for the thickness of perpendicular circuit boards are the same as those of the embodiments illustrated in FIGS. 18 to 29. Thus, description of the same components will be omitted.

With reference to FIG. 30, a rubber socket 1040 is disposed between a semiconductor chip 20 and a stage 30 and electrically connects chip electrode pads 21 of the semiconductor chip 20 and stage electrode pads 31 of the stage 30.

The rubber socket 1040 includes plurality of perpendicular circuit boards 1400 and a plurality of adhesion layers 1405.

Each perpendicular circuit board 1402 includes a rubber substrate 1410 and an electrical connection pattern 1430.

The rubber substrate 1410 has a flat plate shape, and the thickness (t1) of the rubber substrate 1410 is smaller than the distance (D2) between adjacent chip electrode pads 21 and the distance (D1) between adjacent stage electrode pads 31. In this embodiment, the thickness (t) of the rubber substrate 1410 may be less than of the distance (D2) between adjacent chip electrode pads 21 and the distance (D1) between adjacent stage electrode pads 31. In another embodiment, the distance (D3) between adjacent rubber substrates 1410 may be less than half of the distance (D2) between adjacent chip electrode pads 21 and the distance (D1) between adjacent stage electrode pads 31.

When the thickness (t) of the rubber substrate 1410 is less than half of the distance (D2) between adjacent chip electrode pads 21 and the distance (D1) between adjacent stage electrode pads 31, a short circuit is prevented from occurring between adjacent electrode pads 21, 31 such that an electric signal pathway for exactly delivering a signal is made.

According to the above-described embodiment of the present invent ion an electrical connection member is used instead of a wire so as to connect lower electrode parts of a lower film and upper electrode parts of an upper film. In this case, the upper portion of the electrical connection member is connected in parallel to the lower surface of the upper electrode part, the lower portion of the electrical connection member is connected in parallel to the upper surface of the lower electrode part, and the central portion of the electrical connection member is connected to the upper electrode part and lower electrode part in the state where the central portion of the electrical connection member is perpendicularly curved between the upper electrode part and lower electrode part.

When the electrical connection member includes a soft substrate and an electrical connection pattern, external pressure may be effectively dispersed in the case in which an external shock is applied and a semiconductor chip is repeatedly tested.

Additionally, the width of the electrical connection pattern formed on the soft substrate may be controlled such that the surface are of the electrical connection pattern is expanded, thereby reducing resistance.

Additionally, the electrical connection pattern and the soft substrate are integrally formed so as to prevent the electrical connection pattern from being cut, thereby making it possible to increase the lifespan of a rubber socket and improve the credibility of the same.

Additionally, the density of a semiconductor chip is improved. Thus, even when the distance between adjacent chip electrode pads becomes short, the shape of the electrical connection pattern or the gap between attached upper electrode parts is controlled without reducing the distance between stage electrode pads of a stage short such that a test may be easily performed.

Additionally, the shape the electrical connection pattern may be configured to have any shape. Thus, an optimum test device may be provided according to a type of test.

Additionally, parallelism of a thin film patterned film between the upper and lower films is controlled without precise alignment, and an electrical connection member adheres between the upper and lower films, such that an electric signal pathway for exactly delivering a signal may be made.

Additionally, a thermal compression member includes an incline compression part by means of ultrasonic bonding, and heats and compresses the electrical connection pattern with respect to the electrode pads so as to sol couple the electrical connection pattern to the electrode pads, thereby making it possible to increase the lifespan of a rubber socket and improve the credibility of the same.

Additionally, the electrical connection pattern is completely buried inside a rubber layer without sticking out of a rubber socket. Thus, the end portion of a rubber socket is not pushed inward, thereby making it possible to increase the lifespan of the rubber socket, improve the design of the rubber socket and prevent damage to a semiconductor chip for a test.

According to the above-described embodiment of the present invention, a rubber socket may effective disperse external pressure using a plurality of perpendicular circuit boards piled perpendicularly, instead of a wire or a pad, in the case in which an external shock is applied and a semiconductor chip is repeatedly tested.

Additionally, the width of the electrical connection pattern of the perpendicular circuit board may be controlled such that the surface are of the electrical connection pattern is expanded, thereby reducing resistance.

Additionally, the electrical connection pattern and the perpendicular circuit board are integrally formed so as to prevent the electrical connection pattern being cut, thereby making it possible to increase the lifespan of a rubber socket and improve the credibility of the same.

Additionally, the density of a semiconductor chip is improved. Thus, even when the distance between adjacent chip electrode pads becomes short, a high-density semiconductor chip may be easily tested only by controlling the thickness of the perpendicular circuit board.

Additionally, the shape of the electrical connection pattern may be configured to have any shape. Thus, an optimum test device may be provided according to a type of test.

Additionally, the perpendicular circuit boards may be simply piled without the need separately align the perpendicular circuit boards. Thus, the processes of manufacturing perpendicular circuit boards are simplified, the costs incurred to manufacture perpendicular circuit boards are reduced, and an electric signal pathway for exactly delivering a signal is made.

Additionally, manufacturing the perpendicular circuit boards does not separately include a soldering process or a welding process unlike conventional electrode-type and wire-type rubber sockets. Thus, the end portion of a rubber socket is not pushed inward, thereby making it possible to increase the lifespan of the rubber socket, improve the design of the rubber socket and prevent damage to a semiconductor chip during the process of testing the semiconductor chip.

Additionally, the perpendicular circuit board includes a thin buffer film for blocking the rubber substrate from being excessively elastic or deformed so as to protect the electrical connection pattern.

1. A rubber socket comprising:
a lower film comprising a plurality of lower electrode parts coupled to a synthetic resin film;
an upper film spaced apart from the lower film, arranged in parallel with the lower film and comprising a plurality of upper electrode parts;
an electrical connection member physically connecting the lower electrode parts and the upper electrode parts, and comprising a soft substrate, which has a fiat plate shape and is easily bent by an external force, and a plurality of electrical connection patterns which are vertically formed on one lateral surface of the soft substrate and electrically connects the lower electrode parts and the upper electrode parts; and
a rubber layer comprising an elastic material, disposed between the lower film and the upper film, entirely burying the electrical connection members, and constantly maintaining a distance between the lower film and the upper film.

2. The rubber socket according to claim 1, wherein a distance between the upper electrode parts is shorter than a distance between the lower electrode parts, and in each electrical connection member, a distance between the upper portions of adjacent electrical connection patterns is shorter than a distance between the lower portions of the electrical connection patterns.

3. The rubber socket according to claim 1, wherein the electrical connection member further comprises a central opening which is opened and formed between the electrical connection patterns.

4. The rubber socket according to claim 1, wherein the electrical connection member covers the electrical connection patterns and further comprises an upper coating having an upper opening one side of which extends in a direction perpendicular to the direction in which the electrical connection patterns extend, and the soft substrate has a lower opening which is disposed on the opposite side of the lower opening and extends in direction perpendicular to the direction in which the electrical connection patterns extend.

5. A method for manufacturing a rubber socket, which comprises a lower film comprising a plurality of lower electrode parts coupled to a synthetic resin film, an upper film spaced apart from the lower film, arranged in parallel with the lower film and comprising a plurality of upper electrode parts, an electrical connection member comprising a soft substrate having a flat plate shape and easily bent by an external force, and a plurality of electrical connection patterns which are vertically formed on one lateral surface of the soft substrate and electrically connects the lower electrode parts and the upper electrode parts, and a rubber layer disposed between the lower film and the upper film and entirely burying the electrical connection members, comprising:
forming a plurality of primitive lower electrode parts and lower joint parts protruding from the primitive lower electrode parts in the central area of a lower film;
forming a plurality of primitive upper electrode parts and upper joint parts protruding from the primitive upper electrode parts in the central area of an upper film;
coupling the lower portion of the electrical connection pattern and the lower joint part;
coupling the upper portion of the electrical connection pattern and the upper joint part; and
forming a rubber layer between the lower film and the upper film.

6. The method for manufacturing a rubber socket according to claim 5, wherein coupling the lower portion of the electrical connection pattern and the lower joint part comprises welding or soldering the lower portion of the electrical connection pattern and the lower joint part by means of ultrasonic waves and heat in the state where the lower portion of the electrical connection pattern and the lower joint part are pressed.

7. The method for manufacturing a rubber socket according to claim 5, wherein coupling the lower portion of the electrical connection pattern and the lower joint part and coupling the upper portion of the electrical connection pattern and the upper joint part are simultaneously performed.

8. A rubber socket comprising:
a plurality of perpendicular circuit boards perpendicularly piled comprising a rubber substrate which has a flat plate shape extending vertically, is temporarily deformed by an external force and returns to the original shape thereof when the external force is removed, a lower contact part which is disposed only on part of the lower surface of the rubber substrate and is exposed toward the lower portion of the rubber substrate, an upper contact part which is disposed only on part of the upper surface of the rubber substrate and is exposed toward the upper portion of the rubber substrate, and a plurality of electrical connection patterns which comprises a connection part vertically extending and connecting the lower contact part and the upper contact part on one lateral surface of the rubber substrate; and
a plurality of adhesion layers disposed between adjacent perpendicular circuit boards and bonding the adjacent perpendicular circuit boards such that the adjacent perpendicular circuit boards are integrally piled.

9. The rubber socket according to claim 8, wherein the rubber substrate one lateral surface on which the connection part is disposed and which has a flat plate shape and the other lateral surface which is on the opposite side of the connection part and has a concave shape so as to form a buffer space.

10. The rubber socket according to claim 8, wherein the rubber socket further comprises a thin buffer film which is thinner than the rubber substrate, is disposed between the rubber substrate and the electrical connection patterns and has a lower deformation level than the rubber substrate with respect to the external force.

11. A method for manufacturing a rubber socket comprising;
molding silicone rubber or synthetic rubber so as to form a rubber substrate which has a flat plate shape vertically extending, and is temporarily deformed by an external force and returns to the original shape thereof when the external force is removed;
forming a plurality of electrical connection members, which comprise a conductive material and respectively comprise a lower contact part, an upper contact part and a connection part for connecting the lower contact part and the upper coot part, on part of the lower surface, part of the upper surface and one lateral surface of the rubber substrate, so as to form a perpendicular circuit board;
vertically piling a plurality perpendicular circuit boards such that the lower contact parts and upper contact parts are respectively exposed toward the lower and upper portions of the rubber substrate; and
coupling the perpendicular circuit boards vertically piled.

12. The method for manufacturing a rubber socket according to claim 11, further comprising:
forming a thin buffer film, which is thinner than the rubber substrate and has a lower deformation level than the rubber substrate with respect to the external force, on the lower surface, the upper surface and one lateral surface of the rubber substrate,
wherein forming electrical connection members comprises forming the lower contact part, the upper contact part and the connection part on the thin buffer film.
